(19) United States
(12) Patent Application Publication
(10) Pub. No.: US 2026/0094656 A1
(43) Pub. Date: Apr. 2, 2026

(54) CIRCUIT AND METHOD FOR ACCURATELY CLAMPING SOURCE-TO-DRAIN VOLTAGE OF EPROM BIT-CELL

(71) Applicant: Texas Instruments Incorporated, Dallas, TX (US)

(72) Inventors: Rohan Sinha, Bengaluru (IN); Sumanth U, Bengaluru (IN)

(21) Appl. No.: 18/898,944

(22) Filed: Sep. 27, 2024

(51) Int. Cl. G11C 17/18; G11C 17/16

(52) U.S. Cl. CPC G11C 17/18; G11C 17/16

(57) ABSTRACT

A semiconductor device includes a cell transistor coupled to a bitline, a bias transistor coupled to the bitline and to a bias node, and a clamp transistor coupled between the bitline and a clamp node. A memory circuit includes an array of memory cell transistors coupled to respective bitlines, bias transistors having a source, a drain, and a gate, the source of each bias transistor coupled to a respective one of the bitlines, a bias node coupled to the gates of the bias transistors, a current source having first and second terminals, the first terminal coupled to the bias node, and the second terminal coupled to a reference node, and clamp transistors, each having a source, a drain, and a gate, the gate and source of each clamp transistor coupled to a respective one of the bitlines, and the drain of each clamp transistor coupled to a clamp node.

### BACKGROUND

Electrically programmable read only memory (EPROM) memory is a form of electronic memory that maintains bit-cell data when power is removed. Maintaining bit-cell data states for long periods of time is important and is helped by limiting bit-cell drain-to-source potential (Vds) during memory read operations and in standby mode. However, memory array configurations can be subject to leakage current, such as by parasitic capacitance of transistors coupled to memory array bitlines. Pass gate bias transistors can be biased to help control the cell transistor Vds, but the bitlines are floating during standby operation and bias transistors cannot prevent the bitline voltage from decreasing due to standby mode leakage. In addition, unprogrammed or ultraviolet (UV) erased state bit-cells are more sensitive to Vds modulation and can be incorrectly soft-programmed (e.g., falls programming) by repeated read cycles (e.g., a few hundreds/thousands of read cycles).

### SUMMARY

In one aspect, a semiconductor device includes a cell transistor coupled to a bitline, a bias transistor coupled to the bitline and to a bias node, and a clamp transistor coupled between the bitline and a clamp node.

In another aspect, a memory circuit includes memory cell transistors coupled to respective bitlines, bias transistors individually having a source, a drain, and a gate, with the source coupled to a respective one of the bitlines, a bias node coupled to the gates of the bias transistors, a current source having first and second terminals, the first terminal coupled to the bias node, and the second terminal coupled to a reference node, and clamp transistors individually having a source, a drain, and a gate with the gate and source of each clamp transistor coupled to a respective one of the bitlines, and the drain of each clamp transistor coupled to a clamp node.

In a further aspect, a method includes forming bias transistors on or in a semiconductor layer, the bias transistors in a first row and spaced apart from one another along a first direction and having respective gates with a first width along a second direction that is orthogonal to the first direction, as well as forming clamp transistors in a parallel second row on or in the semiconductor layer, the clamp transistors spaced apart from one another along the first direction and spaced apart from respective ones of the bias transistors along the second direction and having respective gates with a second width along the second direction that is less than the first width. The method includes connecting a source of the bias transistors to a respective one of bitlines of a memory array, connecting gates of the bias transistors to a bias node, and connecting each of the clamp transistors between a clamp node and a respective one of the bitlines.

### BRIEF DESCRIPTION OF THE DRAWINGS

FIG. 1 is a schematic diagram of a memory circuit with clamp transistors to limit bit-cell drain-source voltage to mitigate drift towards GND independent of leakage current with a shared sense amp for multiple bitlines.

FIG. 1A is a partial schematic diagram of a portion of the memory circuit of FIG. 1.

FIGS. 1B1 and 1B2 are partial top plan views of an example layout of a portion of the memory circuit with clamp transistors of FIGS. 1 and 1A.

FIG. 1C is a partial sectional side elevation view of the memory circuit layout taken along line 1C-1C of FIGS. 1B1 and 1B2.

FIG. 1D is a partial sectional side elevation view of the memory circuit layout taken along line 1D-1D of FIG. 1B1.

FIG. 1E is a partial schematic diagram of a portion of a different memory circuit with no bitline clamping transistors.

FIGS. 1F1 and 1F2 are partial top plan views of an example layout of a portion of the memory circuit of FIG. 1E.

FIG. 2 is a schematic diagram of a memory circuit with clamp transistors to limit bit-cell drain-source voltage to mitigate drift towards GND independent of leakage current with individual bitline sense amps.

FIG. 3A is a graph of signals in the memory circuit of FIGS. 1-1D with clamp transistors to limit bit-cell drain-source voltage to mitigate bitline drift towards ground for multiple read operations.

FIG. 3B is a graph of signals in the memory circuit of FIGS. 1E, 1F1 and 1F2 showing downward bit-cell drain-source voltage drift for multiple read operations without bitline clamp transistors.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means+/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, first, second, and third wells, etc., for ease of description in connection with a particular drawing, where such are not to be construed as limiting with respect to the claims. Various disclosed structures and methods of the present disclosure may be beneficially applied to manufactured electronic apparatus such as an integrated circuit or other semiconductor device. While such examples may be expected to provide various improvements, no particular result is a requirement of the present disclosure unless explicitly recited in a particular claim.

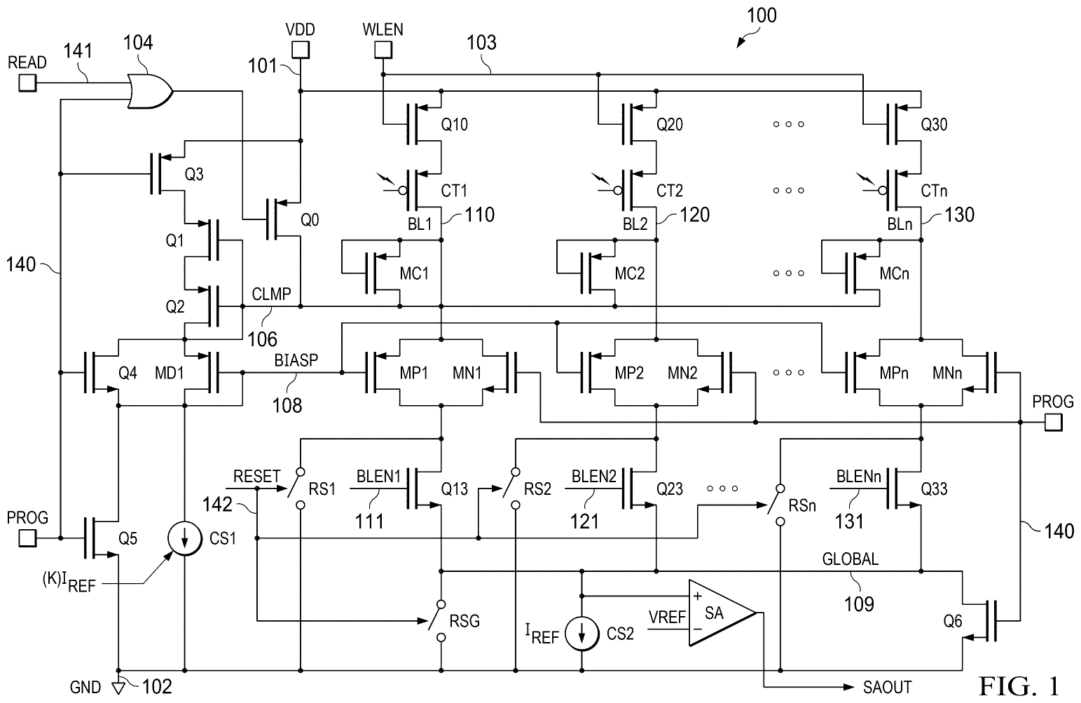

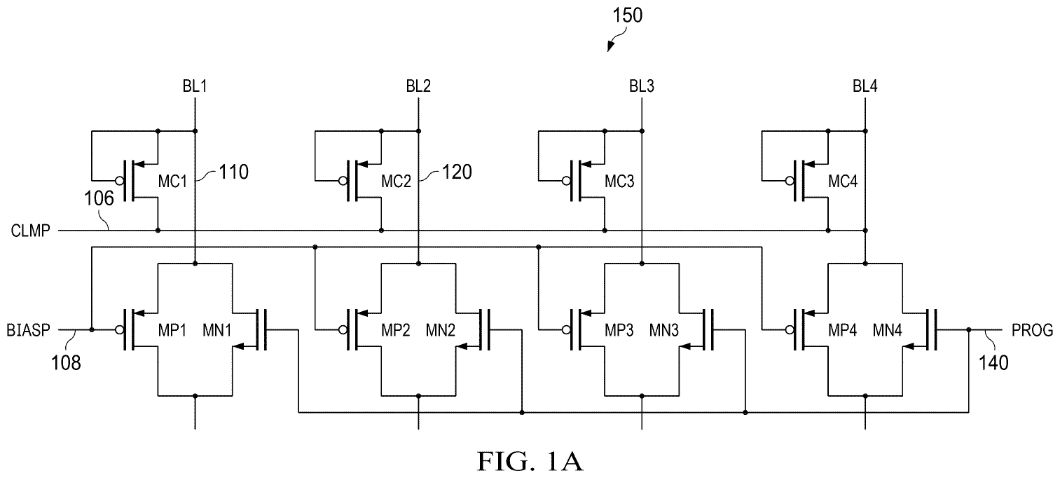

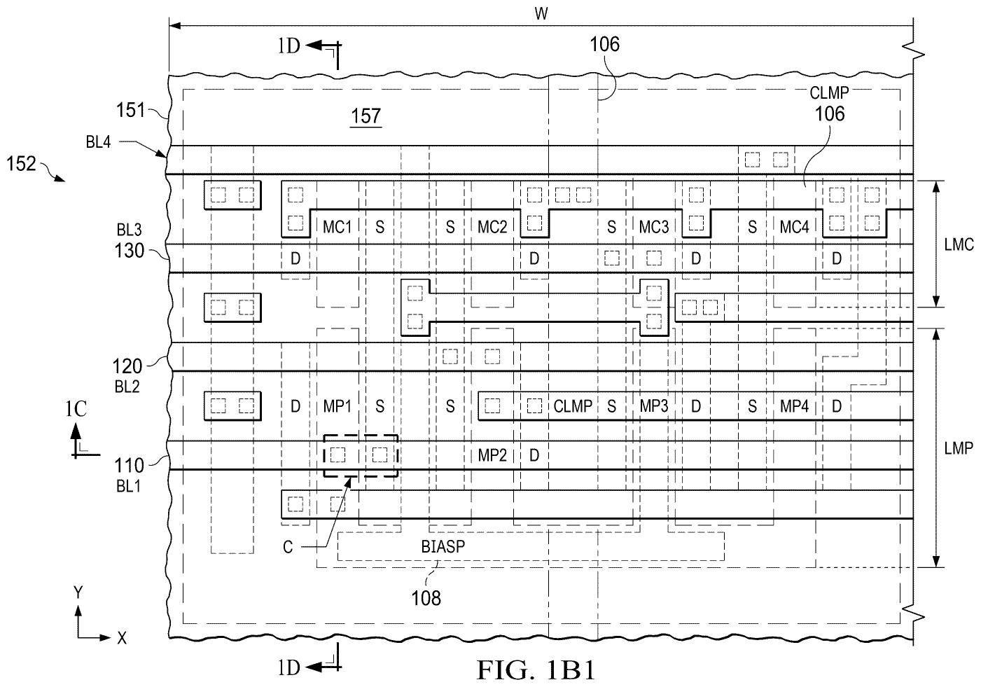

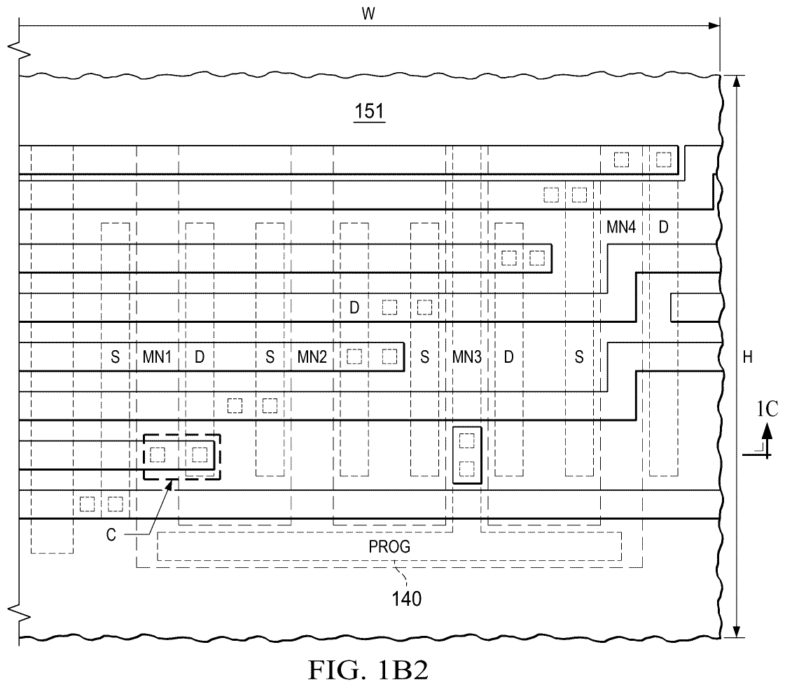

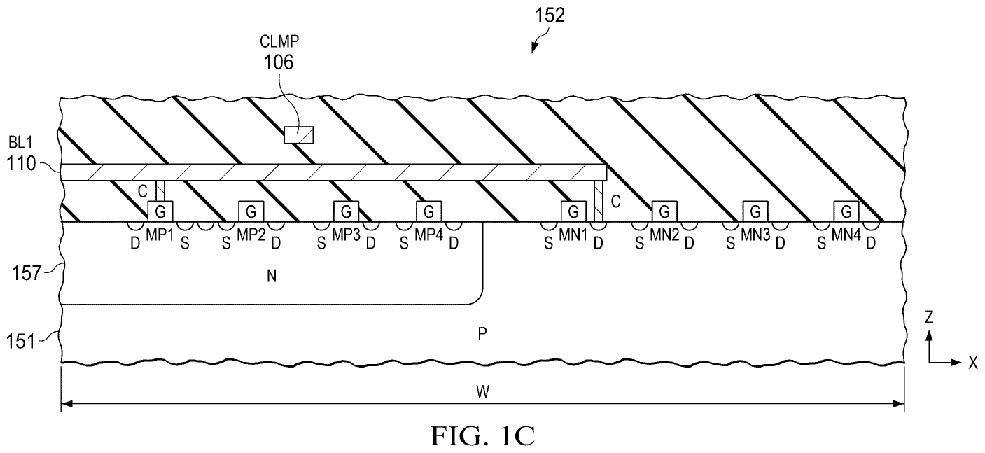

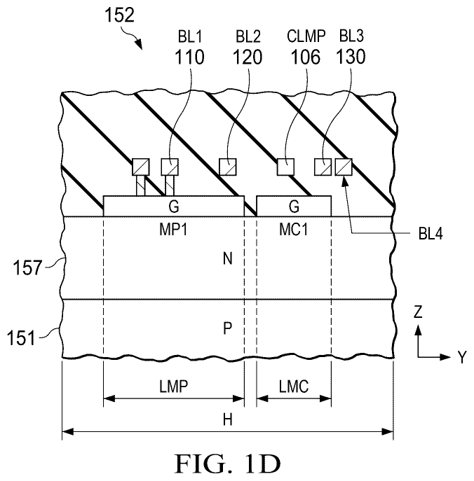

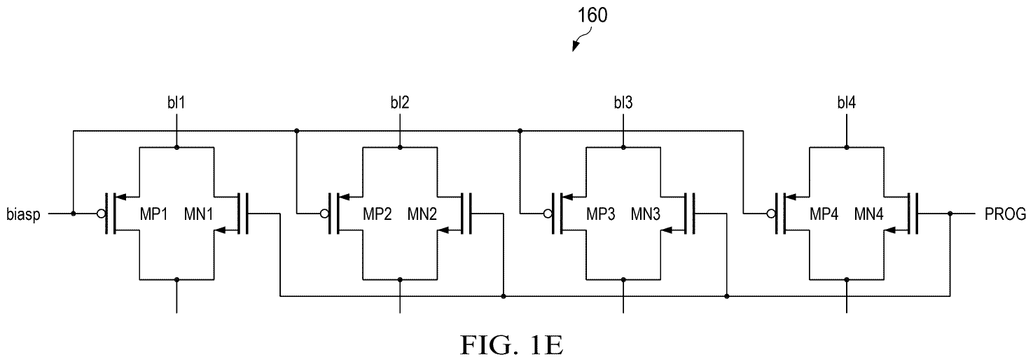

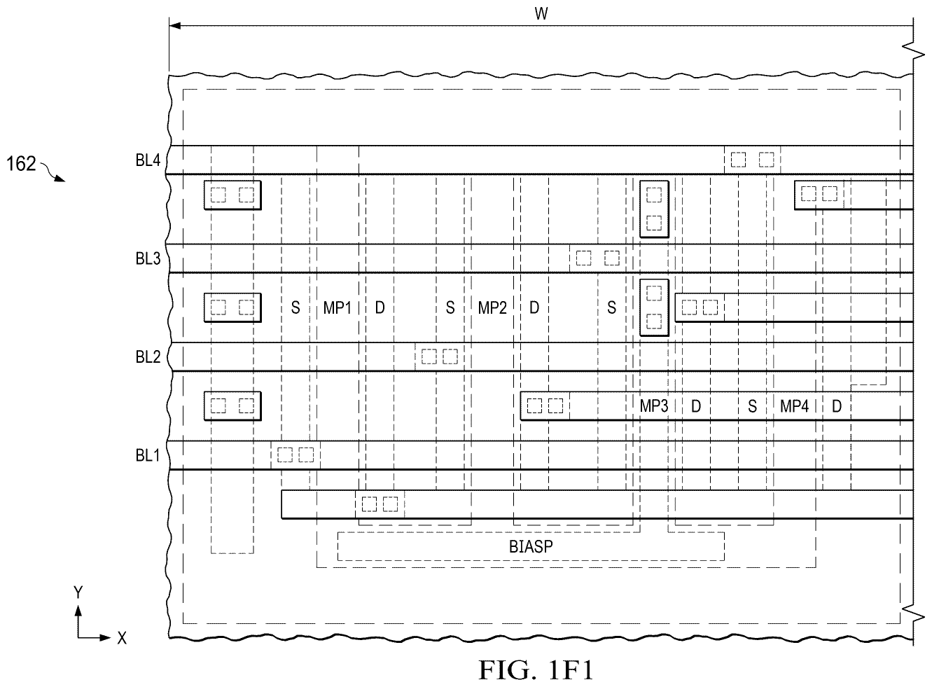

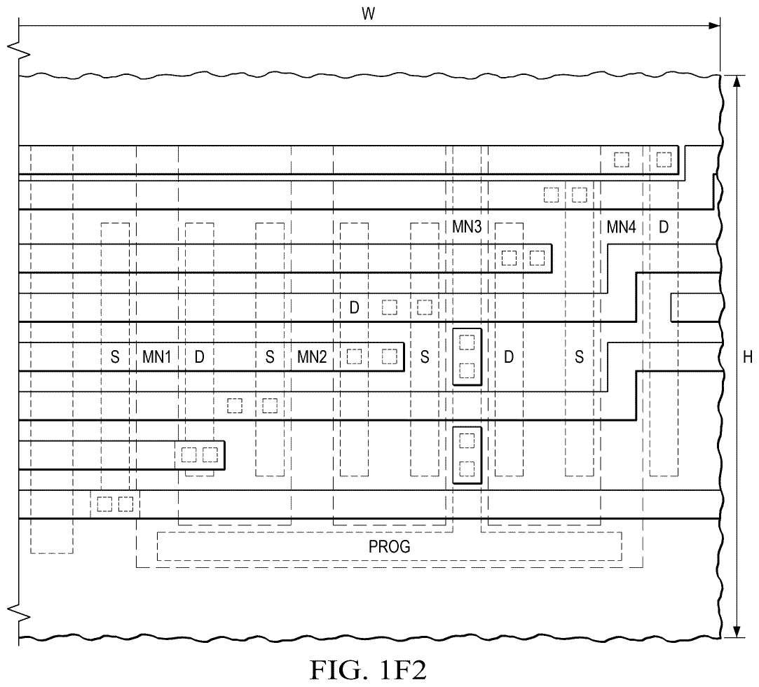

Referring initially to FIGS. 1 and 1A, FIG. 1 shows a schematic diagram of a semiconductor device 100 with an EPROM memory circuit having power supply connections including a supply node 101 (e.g., powered by a supply voltage signal “VDD”) and a reference node 102 (e.g., a ground or common reference, labeled “GND” without limitation, or may be referred to generally as “VSS”), and FIG. 1A shows a schematic view 150 of a portion of the memory circuit of FIG. 1. The memory circuit includes an array of nonvolatile bit cells or memory cell transistors CT1, CT2, . . . , CTn (e.g., hereinafter collectively CT1-CTn). The cell transistors CT1-CTn provide individual nonvolatile storage to store and maintain a respective a bitcell state (e.g., erased or programmed) when the semiconductor device 100 is powered down. The cell transistors CT1-CTn are operative when the device 100 is powered and operating in different modes for read, program, and standby operation.

The cell transistors CT1-CTn are p-channel (e.g., PMOS) transistors that each include a source and a drain that is coupled (e.g., directly connected) to a corresponding bitline BL1, BL2, . . . , BLn (e.g., hereinafter collectively BL1-BLn). The cell transistors CT1-CTn are arranged in logical rows and columns. FIG. 1 shows one example row with an integer number n of the cell transistors CT1-CTn in corresponding columns along the respective bitlines BL1-BLn. In FIG. 1, the first illustrated bitline BL1 is also labeled 110, the second illustrated bitline BL2 is labeled 120, and the last (e.g., n^{th}) illustrated bitline BLn is labeled 130. The cell transistors CT1-CTn and associated circuitry can be physically arranged in orthogonal rows and columns, although not a requirement of all possible implementations (e.g., FIGS. 1B1 and 1B2 below).

A wordline 103 is associated with the illustrated cell transistors CT1-CTn. The memory circuit can include further wordlines (not shown). Memory control circuitry (not shown) provides an active low wordline enable signal WLEN to select the illustrated cell transistors CT1-CTn during read and program operating modes when the semiconductor device 100 is powered and operating. The source of the first cell transistor CT1 is coupled (e.g., directly connected) to a drain of a p-channel (e.g., PMOS) enable transistor Q10. The source of the enable transistor Q10 is coupled (e.g., directly connected) to the supply node 101, and the gate of the enable transistor Q10 is coupled (e.g., directly connected) to the wordline 103. The wordline enable signal WLEN selectively turns on the enable transistor Q10 (e.g., active low wordline enable signal WLEN) to couple the source of the cell transistor CT1 to the supply node 101 for read or program operations. For standby operation, the wordline enable signal WLEN (e.g., low) turns off the PMOS enable transistor Q10 in order to disconnect the source of the cell transistor CT1 from the supply node 101.

Similarly, enable transistor Q20 has a source coupled (e.g., directly connected) to the supply node 101, a gate coupled (e.g., directly connected) to the wordline 103 and a drain coupled (e.g., directly connected) to the second bitline 120 to selectively enable read or program operations for the second cell transistor CT2. Another enable transistor Q30 has a source coupled (e.g., directly connected) to the supply node 101, a gate coupled (e.g., directly connected) to the wordline 103, and a drain coupled (e.g., directly connected) to the n^{th} bitline 130 to selectively enable read or program operations for the n^{th} cell transistor CTn based on the wordline enable signal WLEN.

The semiconductor device 100 also includes a logic gate 104 to provide an output signal to a PMOS clamp bypass transistor Q0 based on an operating mode selected by the memory control circuitry (not shown). The logic gate 104 in the illustrated example is an OR gate with a first input 140 coupled to receive a program control signal PROG, and a second input 141 coupled to receive a read control signal READ. In bypass mode operation, both control signals PROG and READ are low, and the output of the logic gate 104 is low, causing the clamp bypass transistor Q0 to turn on and couple a clamp node 106 to the supply node 101. The clamp node 106 has a clamp voltage signal CLMP when the semiconductor device 100 is powered and operating. During read or program operation, the output of the logic gate 104 is high and the clamp bypass transistor Q0 is turned off.

The memory circuit also includes bias transistors MP1, MP2, MP3 (FIG. 1A), MP4 (FIG. 1A, . . . , MPn (e.g., hereinafter collectively MP1-MPn). Each of the bias transistors MP1-MPn in the illustrated example is a p-channel (e.g., PMOS) transistor having a source, a drain, and a gate. The source of each bias transistor MP1 in one example is coupled (e.g., directly connected) to a respective one of the bitlines BL1-BLn. The gate of each bias transistor MP1 in one example is coupled (e.g., directly connected) to a bias node 108. The bias node 108 has a bias voltage signal BIASP when the semiconductor device 100 is powered and operating.

A current source CS1 is coupled between the bias node 108 and the reference node 102. The current source CS1 has a first terminal coupled to the bias node 108 and a second terminal coupled to the reference node 102. In powered operation, the current source CS1 sinks a current K(I_{REF}) from the bias node 108 to the reference node 102. A p-channel transistor MD1 (e.g., PMOS) has a gate and drain that are coupled (e.g., directly connected) to the bias node 108, as well as a source that is coupled (e.g., directly connected) to the clamp node 106. An n-channel (e.g., NMOS) transistor Q4 has a drain coupled (e.g., directly connected) to the clamp node 106 and a source coupled (e.g., directly connected) to the bias node 108, with a gate coupled (e.g., directly connected) to the first input 140. The transistor Q4 is turned on by the program control signal PROG to couple the clamp node 106 to the bias node 108 during programming mode operation. Another n-channel (e.g., NMOS) transistor Q5 has a drain coupled (e.g., directly connected) to the bias node 108 and a source coupled (e.g., directly connected) to the reference node 102, as well as a gate coupled (e.g., directly connected) to the first input 140. The transistor Q5 operates to selectively bypass the current source CS1 during programming mode operation based on the program control signal PROG. During programming mode operation, the transistors Q4 and Q5 turn on to bring the clamp node voltage CLMP and the bias node voltage BIASP to the reference node voltage GND.

P-channel (e.g., PMOS) transistors Q1 and Q2 have gates coupled (e.g., directly connected) to the clamp node 106, with a drain of the transistor Q1 coupled (e.g., directly connected) to a source of the transistor Q2. A drain of the transistor Q2 is coupled (e.g., directly connected) to the clamp node 106. A p-channel (e.g., PMOS) transistor Q3 has a gate coupled (e.g., directly connected) to the first input 140, a source coupled (e.g., directly connected) to the supply node 101, and a drain coupled (e.g., directly connected) to the source of the transistor Q1.

During standby and read operations, the transistors Q4 and Q5 are off and the current source CS1 keeps the transistor MD1 on. In this condition, the gate of the transistor MD1 and the bias node 108 have the bias node voltage BIASP, and the clamp node 106 has the clamp node voltage CLMP that is the threshold voltage of the transistor MD1 above the bias node voltage BIASP. In one example, the p-channel transistors MD1 and MP1 are of approximately equal size and have the same or approximately equal threshold voltages, such that the bitline voltages of the bitlines 110, 120, and 130 are approximately equal to the bias node voltage BIASP. During standby and read mode operation, the transistor Q3 is on and the clamp node and bitline voltages are nominally maintained at approximately two diode drops below the supply voltage VDD (e.g., VDD-approximately 1.4 V) by the on state operation of the bias transistors MP1-MPn. However, leakage from the bitlines 110, 120, 130 can occur, such as during standby mode operation, which can cause the bitline voltages to drift lower.

To help counteract excessive downward drift of the bitline voltages during standby mode operation, the semiconductor device 100 includes p-channel (e.g., PMOS) clamp transistors MC1, MC2, MC3 (FIG. 1A), MC4 (FIG. 1A), . . . , MCn (e.g., hereinafter collectively MC1-MCn), each with a source, a drain, and a gate. The gate and source of each of the clamp transistors MC1-MCn is coupled (e.g., directly connected) to a respective one of the bitlines 110, 120, 130, and the drain of each clamp transistor MC1-MCn is coupled (e.g., directly connected) to the clamp node 106. The clamp transistors MC1-MCn are small sized PMOS transistors coupled in diode configurations. Other types and forms of clamping circuits or components can be used in other implementations, such as junction diodes, Zener diodes, other forms of diode-connected transistors, etc. (not shown). During programming mode operation (e.g., PROG high), the transistor Q0 is turned off, and the transistors Q4 and Q5 are turned on to couple the clamp node 106 and the bias node 108 to the supply node 101. This ensures that the clamp transistors MC1-MCn do not disturb programming of the cell transistors CT1-CTn. During standby mode operation (e.g., PROG and READ low), Q0 is turned on, the transistors Q4, and Q5 are off, and the clamp node voltage CLMP is approximately VDD-1.4 V.

Any leakage that tends to reduce the bitline voltages of the bitlines 110, 120, and/or 130 during standby mode operation is counteracted by the respective one of the clamp transistors MC1-MCn. In one implementation, this selective clamping operation of the clamp transistors MC1-MCn helps ensure that the drain-source voltage of the cell transistors CT1-CTn is less than a desired safe operating margin (e.g., approximately 2 V in one implementation). The clamp transistors MC1-MCn advantageously allow a significantly long time period during powered operation in standby mode to counteract any long-term bitline voltage drift caused by leakage in the semiconductor device 100, with the clamp transistors MC1-MCn operating only in response to leakage coupling or other circumstances during standby mode operation that tend to reduce the bitline voltages. The coupling of the clamp transistors MC1-MCn to the bitlines 110, 120, 130 provides selective registration of the bitline voltages to mitigate long-term degradation of the operation of the cell transistors CT1-CTn as well as mitigating or preventing falls programming of the cell transistors CT1-CTn.

Moreover, the operation of the clamp transistors MC1-MCn to maintain the drain-source voltage of the of the cell transistors CT1-CTn within a desired range (e.g., less than 2 V) helps to maintain the threshold gate-source voltage of the bias transistors MP1-MPn to mitigate inadvertent turning off during read operations. In this manner, sensing circuitry of the memory cell will not incorrectly interpret an erased cell transistors CT1-CTn as being programmed because the associated bias transistor MP1-MPn is turned off by the excessive drain-source voltage of the cell transistor CT1-CTn. The clamp transistors MC1-MCn provide an on-board circuit solution that allows the memory circuit to be continuously operated for an extended period of time without requiring power down and power up or bit cell read-refresh operations to promote long term nonvolatile data storage and mitigate cell transistor stress or degradation.

The clamp transistors MC1-MCn in the example memory circuit in FIG. 1 selectively regulate or limit the bit cell drain-source voltage to mitigate bitline voltage drift towards GND independent of leakage current with a shared sense amp for multiple bitlines. This example provides individual n-channel (e.g., NMOS) select transistors MN1, MN2, MN3 (FIG. 1A), MN4 (FIG. 1A), . . . , MNn (e.g., hereinafter collectively MN1-MNn) coupled in parallel with the respective bias transistors MP1-MPn. The individual select transistors MN1-MNn have drains coupled (e.g., directly connected) to a corresponding one of the bitlines 110, 120, 130, sources, and gates that are coupled to the first input 140. The select transistors MN1-MNn operate according to the program signal PROG (e.g., active high) to selectively bypass the respective bias transistors MP1-MPn and couple of the respective bitlines 110, 120, 130 to an associated bitline enable transistor Q13, Q23, Q33.

The example memory circuit of FIG. 1 includes a shared sense amp SA in order to sense the data state (e.g., erased or programmed) of a selected one of the cell transistors CT1-CTn during read mode operation, and the sense amp SA has an output that provides a sense amp output signal SAOUT with a voltage that represents the sensed data state represented by a voltage signal GLBL on a global bitline 109. The memory circuit in this example also includes bitline specific reset switches RS1, RS2, . . . , RSn (e.g., hereinafter collectively RS1-RSn) coupled between the reference node 102 and the source of a respective one of the select transistors MN1-MNn. The memory circuit also includes a global reset switch RSG coupled between the reference node 102 and the global bitline 109. The global and bitline specific reset switches RSG and RS1-RSn are operated according to a RESET control signal at a third input 142 from the memory control circuitry (not shown) to selectively reset voltage of the global bitline 109 and the sources of the select transistors MN1-MNn to GND.

In one read operation example, the memory control circuitry asserts the RESET control signal to initially ground the global bitline 109 and the sources of the select transistors MN1-MNn, then de-asserts the RESET control signal prior to coupling a selected one of the bitlines. With the global bitline 109 and the sources of the select transistors MN1-MNn reset, the memory control circuitry asserts the READ signal and the wordline enable signal WLEN, and turns on a selected one of the bitline enable transistor Q13, Q23, Q33 by asserting a corresponding bitline enable signal BLEN1, BLEN2, . . . , or BLENn at a gate terminal 111, 121, . . . , or 131 of the bitline enable transistor Q13, Q23, . . . , or Q33. The selected one of the cell transistors CT1-CTn is connected through the corresponding select transistor MN1-MNn and bitline enable transistor Q13, Q23, . . . or Q33 to the global bitline 109.

The sense amp SA has a noninverting input coupled (e.g., directly connected) to the global bitline 109, and a second current source CS2 is coupled between the global bitline 109 and the reference node 102 to conduct a current I_{REF} from the global bitline 109 to the reference node 102. The connected one of the cell transistors CT1-CTn will conduct a current in one of two distinguishable ranges based on the program state, for example, a low current range for an erased (unprogrammed) memory cell or a higher current range for a programmed cell. The sense amp SA compares the global bitline voltage GLBL to a reference voltage VREF and outputs the sense amp output signal SAOUT with a voltage that represents the sensed data state.

FIGS. 1B1 and 1B2 show an example layout 152 of a portion of the memory circuit generally corresponding to the bitlines BL1-BL4, the clamp transistors MC1-MC4, the bias transistors MP1-MP4, and the select transistors MN1-MN4 with the clamp node 106 and the bias node 108 of FIGS. 1 and 1A. FIG. 1C shows a partial sectional view along line IC-IC of FIGS. 1B1 and 1B2 and FIG. 1D shows a partial sectional side view along line ID-ID of FIG. 1B1. The partial top view of FIGS. 1B1 and 1B2 shows the four example bitlines BL1-BL4 extending along a first direction X, with polysilicon gate structures and implanted source and drain regions of the clamp transistors MC1-MC4, the bias transistors MP1-MP4, and the select transistors MN1-MN4 extending along an orthogonal second direction Y.

The illustrated partial layout 152 includes four instances of the n-channel select transistors MN1-MN4 in a p-type semiconductor layer 151 (FIGS. 1B and 1C). The partial layout 152 also includes four instances of the p-channel clamp transistors MC1-MC4 (FIG. 1B1) and bias transistors MP1-MP4 (FIGS. 1B1 and 1C) in an n-type implanted region or well 157 in the semiconductor layer 151. As shown in FIGS. 1B1 and 1B2, the illustrated 4-cell unit of the layout 142 has a width W along the first direction X (also shown in FIG. 1C) and a height H along the second direction Y (also shown in FIG. 1D). As further shown in FIGS. 1B2-1D, the select transistors MN1-MN4, clamp transistors MC1-MC4 and the bias transistors MP1-MP4 have gate electrodes G, such as polysilicon, etc., as well as implanted source and drain regions S and D, respectively. As shown in FIGS. 1B1-1D, the bitlines BL1-BL4 are formed in a first metallization level above the semiconductor layer 151 along the first direction X.

The clamp transistors MC1-MC4 have gates and sources directly connected to the respective bitlines BL1-BL4 by conductive metal contacts between the first metallization level and the polysilicon gate structures and the semiconductor layer 151. The individual bitlines BL1-BL4 are directly connected by corresponding conductive metal contacts to the gate and source of the respective clamp transistors MC1-MC4, and the bitlines BL1-BL4 are directly connected to the source S of the respective bias transistors MP1-MP4 and to the drain D of their respective select transistors MN1-MN4. FIG. 1C shows example conductive metal contacts C that directly connect bitline BL1 to the gate G of the bias transistor MP1 and to the drain D of the select transistor MN1.

The drains D of the clamp transistors MC1-MC4 are connected to the clamp node 106 as schematically shown in FIG. 1A. The clamp node 106 is routed along the second direction Y through the illustrated portion of the layout 152 in a second metallization level above the first metallization level as shown in FIGS. 1B1, 1B2 and IC. The clamp node 106 (that routes the clamp voltage signal CLMP indicated in FIGS. 1C and 1D) is routed along the first direction X by corresponding metal features of the first metallization level (e.g., FIGS. 1B1, 1B2 and 1D). As further shown in FIGS. 1B1 and 1B2, the illustrated portion of the example layout 152 includes further metallization routing structures and features for the bias node 108 and the first input 140 (for the PROG control signal).

As further shown in FIGS. 1B1 and 1D, the bias transistors MP1-MP4 have a first width LMP (e.g., approximately equal to the length of the polysilicon gate structure G of the first bias transistor MP1 in FIG. D). The clamp transistors MC1-MC4 have a second width LMC (e.g., approximately equal to the length of the polysilicon gate structure G of the first clamp transistor MC1 in FIG. 1D). In certain implementations, the first width LMP is greater than the second width LMC, and the bias transistors MP1-MP4 have higher drive current capability than the clamp transistors MC1-MC4. In the illustrated example, the first width LMP is greater than twice the second width LMC, for example, LMP is approximately 3×LMC. Making the clamp transistors MC1-MCn smaller than the associated bias transistors MP1-MPn helps to ensure that the clamp transistors MC1-MCn do not turn on during read operations when the associated bias transistors MP1-MPn are turned on.

FIG. 1E shows a partial schematic diagram of a portion of an example baseline memory circuit 160 with four bitlines bl1-bl4 with no bitline clamping transistors. FIGS. 1F1 and 1F2 show a partial top view of an example layout 162 of a portion of the baseline memory circuit 160 of FIG. 1E. In this example, the baseline circuit includes p-channel (e.g., PMOS) bias transistors MP1-MP4 and n-channel (e.g., NMOS) transistors MN1-MN4 interconnected as shown in FIG. 1E and generally operational as described above. The example baseline layout 162 in FIGS. 1F1 and 1F2 shows the bitlines bl1-bl4 extending along the first direction X. As shown in FIGS. 1F1 and 1F2, the baseline layout 162 has the same width W along the first direction X and a height H along the second direction Y as the example layout 152 in FIGS. 1A-1D. As shown in FIGS. 1A-1F2, the inclusion of the clamp transistors MC1-MC4 does not result in an area penalty, where the illustrated 4-bit layouts 152 and 162 occupy the same circuit area.

In addition, the layout example 152 in FIGS. 1B1-1D advantageously provides higher drive current capability of the bias transistors MP1-MP4 compared to that of the clamp transistors MC1-MC4, with the layout 152 accommodating the routing and interconnection of the clamp transistors MC1-MC4 and the clamp node 106 to provide improved circuit performance without adding cost or occupying any extra area.

The memory circuitry of FIGS. 1-1D can be manufactured using suitable wafer processing and integrated circuit fabrication processes and equipment (not shown). One example can include transistor formation in processing a semiconductor wafer to form the bias transistors MP1-MPn on or in a semiconductor layer 151 of a wafer in a first row and spaced apart from one another along the first direction X. The formation of the bias transistors MP1-MPn provides the respective gates G with the first width LMP along a second direction Y (e.g., FIGS. 1B1, 1B2 and ID above). The transistor fabrication in this example also includes forming the clamp transistors MC1-MCn in a parallel second row on or in the semiconductor layer 151, where the clamp transistors MC1-MCn are spaced apart from one another along the first direction X and spaced apart from respective ones of the bias transistors MP1 along the second direction Y (e.g., FIGS. 1B1 and 1B2). The fabricated clamp transistors MC1-MCn have respective gates G (FIG. 1D) with the second width LMC along the second direction Y that is less than the first width LMP, for example, less than half the first width LMP (e.g., LMP is approximately equal to 3×LMC). The fabrication in one example also includes connecting a source of the bias transistors MP1-MPn to a respective bitline BL1-BLn of a memory array, connecting gates of the bias transistors MP1-MPn to the bias node 108, and connecting each of the clamp transistors MC1-MCn between the clamp node 106 and a respective one of the bitlines BL1-BLn. The method in one example also includes connecting a source and gate of each of the clamp transistors MC1-MCn to the respective one of the bitlines BL1-BLn and connecting a drain of each of the clamp transistors MC1-MCn to the clamp node 106.

In certain examples, the fabrication of the semiconductor device 100 may further include forming the bitlines BL1-BLn to extend above the semiconductor layer 151 along the first direction X, for example, as shown in FIGS. 1B1-1D, with the bitlines BL1-BLn spaced apart from one another along the second direction Y and above the bias and clamp transistors MP1-MPn and MC1-MCn (e.g., FIGS. 1B1, 1B2 and 1D), and forming the clamp node CLMP above the bitlines BL1-BLn along the second direction Y (e.g., FIGS. 1B1, 1B2 and 1C).

Illustrated examples (e.g., FIGS. 1-1D) advantageously provide the extra reliability and reduced likelihood of false reading or false programming by mitigating or preventing bitline voltage drift towards ground (e.g., toward GND or otherwise away from the supply voltage VDD) with no extra overhead in layout area or manufacturing cost of a memory array compared to the baseline design described above in connection with FIGS. 1E, IF1 and 1F2. The examples having smaller clamp transistors compared with the bias transistors (e.g., MP1:MC1 is approximately 3:1 help ensure that the clamp transistors MC1-MCn do not conduct if the associated bias transistor MP1-MPn is turned on, for example, during read operations. The described examples, moreover, help to control and limit the drain-source voltage of the cell transistors CT1-CTn (e.g., at or below 1.5-2.0 V in one example) to mitigate or avoid cell transistor degradation and extend the reliability till end of life operation and undesired turn off of the associated bias transistor MP1-MPn, without having to periodically power down and power up the memory circuitry and/or periodically refresh the stored memory data states. In addition, the provision of the clamp transistors MC1-MCn limits the drain-source voltage of the cell transistors CT1-CTn even in the presence of leakage and coupling at an associated bitline and helps to mitigate or avoid unwanted soft programming of a UV erased cell transistor CT1-CTn during read and standby conditions. In particular, the clamp transistors MC1-MCn can operate in the event of lowered bitline voltage in read and standby operation to provide coupling to the supply node 101 to mitigate undesired charge extraction from the floating gate of the cell transistor CT1-CTn to mitigate or avoid false programming, particularly of erased cell transistors CT1-CTn.

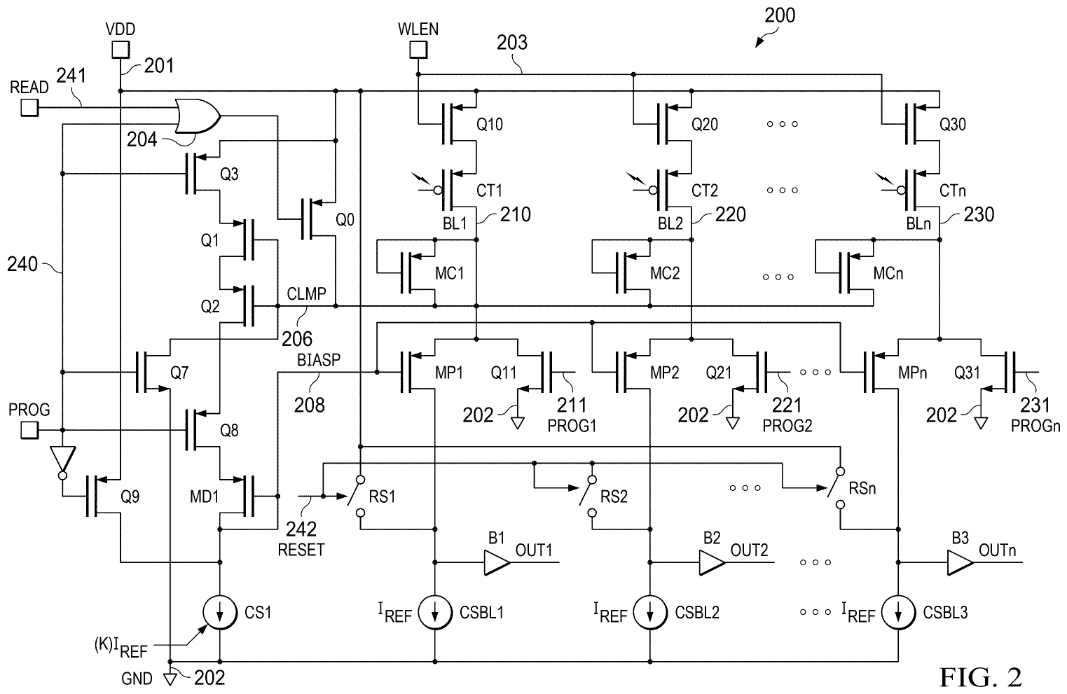

FIG. 2 shows another example semiconductor device 200 with a memory circuit having clamp transistors to limit bit-cell drain-source voltage to mitigate drift towards GND independent of leakage current with individual bitline sense amps (e.g., buffers B1, B2, . . . , B3) instead of multiplexing and switching circuit for using a shared single sense amp (e.g., SA in FIG. 1 above). The semiconductor device 200 has an EPROM memory circuit with power supply connections including a supply node 201 (e.g., powered by a supply voltage signal “VDD”) and a reference node 202 (e.g., a ground or common reference, labeled “GND” or may be referred to generally as “VSS”). The device 200 also includes an array of nonvolatile bit cells or memory cell transistors CT1, CT2, . . . , CTn (e.g., CT1-CTn) that are configured to provide individual nonvolatile storage to store and maintain a respective a bitcell state (e.g., erased or programmed) when the semiconductor device 200 is powered down. The cell transistors CT1-CTn are operative when the device 200 is powered and operating in different modes for read, program, and standby operation. The semiconductor device 200 of FIG. 2 includes structures and features that may have the same reference designators or numbers as in FIGS. 1-1D, and which are or can be generally as described above. In addition, the example device 200 of FIG. 2 includes structures and/or features 201-203, 206, 208, 210, 220, 230 which can in the illustrated and other examples with same or similar to the respective structures and/or features 101-103, 106, 108, 110, 120, 130 as described above in connection with FIGS. 1-1D unless otherwise set forth or described differently hereinafter.

The memory circuit in the device 200 of FIG. 2 provides rows and columns of cell transistors arranged along the illustrated and other wordlines and an integer number “n” bitlines. In addition, the example of FIG. 2 includes the bias transistors MP1-MPn coupled (e.g., directly connected) to respective ones of the bitlines 210, 220, . . . , 230 and to the bias node 208, as well as the clamp transistors MC1-MCn coupled (e.g., directly connected) to a clamp node 206 and to a respective one of the bitlines 210, 220, . . . , 230 to provide the above-described benefits with respect to data retention without false programming or false reading even in the presence of bitline leakage and/or multiple read cycles.

The memory circuitry in FIG. 2 includes individual n-channel (e.g., PMOS) programming transistors Q11, Q21, . . . , Q31 each having a source coupled to a respective one of the bitlines 210, 220, 230, and a source coupled (e.g., directly connected to) to the reference node 202. The first programming transistor Q11 has a gate 211 coupled to receive a first program signal PROG1, the second program transistor Q21 has a gate 222 configured to receive a second program signal PROG2, and the final illustrated program transistor Q31 has a gate 231 configured to receive a final (e.g., n^{th}) program signal PROGn from memory control circuitry (not shown) for individually programming the associated cell transistor CT1-CTn, and a global program signal PROG is asserted at the first input 240 (e.g., active high) in the programming mode to provide the second input to the logic gate 204 to operate the transistor Q0 for selectively coupling the clamp node 206 to the supply node 201. The PROG control signal is inverted by an inverter coupled to the gate of a further transistor Q9 to couple the bias node 208 and the upper terminal of the current source CS1 to the supply node 201 in programming mode.

The circuit in FIG. 2 also includes an n-channel (e.g., NMOS) transistor Q7 coupled between the clamp node 106 and the reference node 102. The transistor Q7 has a drain coupled to the clamp node 206, a source coupled to the reference node 202, and a gate coupled to the first input 240 to receive the PROG control signal. The transistor Q7 operates to selectively couple the clamp node 206 to the reference node 202 during programming mode operation. The example of FIG. 2 also includes a p-channel (e.g., PMOS) transistor Q8 with a source coupled to the clamp node 206, a gate coupled to the input 240, and a drain coupled to the source of the transistor MD1.

The circuit in FIG. 2 also includes reset switches RS1, RS2, . . . , RSn operated by a shared reset control input 242 according to a reset control signal RESET to selectively couple the drain of the respective bias transistors MP1-MPn to the supply node 201, for example, in preparation for or as part of a read operation. The drain of each respective bias transistor MP1-MPn is coupled to the input of a respective one of the buffers B1-B3 and to a first terminal of an associated current source CSBL1, CSBL2, . . . , CSBLn which have respective second terminals coupled to the reference node 202. This allows concurrent reading of all the bitlines 210, 220, 230 in a single operation, with the buffers B1-B3 providing respective output bit signals OUT1, OUT2, . . . , OUTn to represent the program state of the respective cell transistor CT1-CTn.

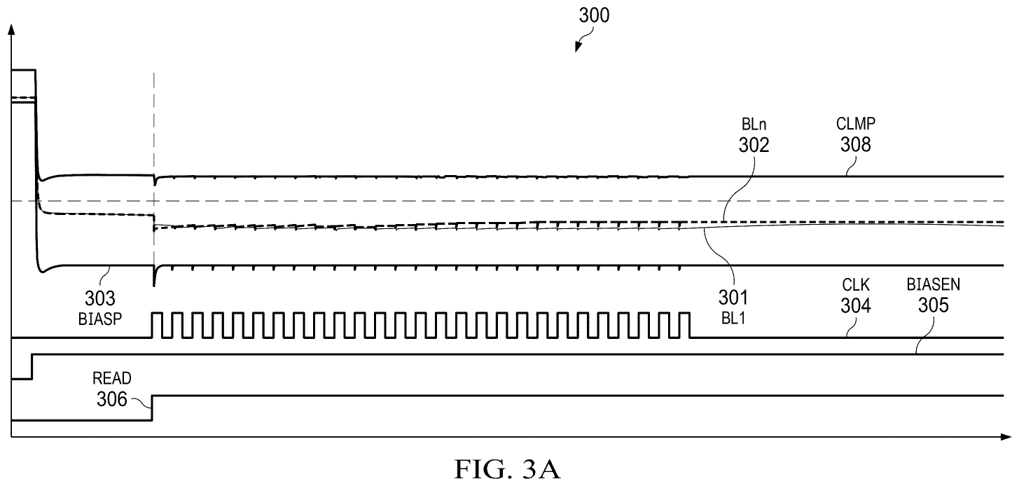

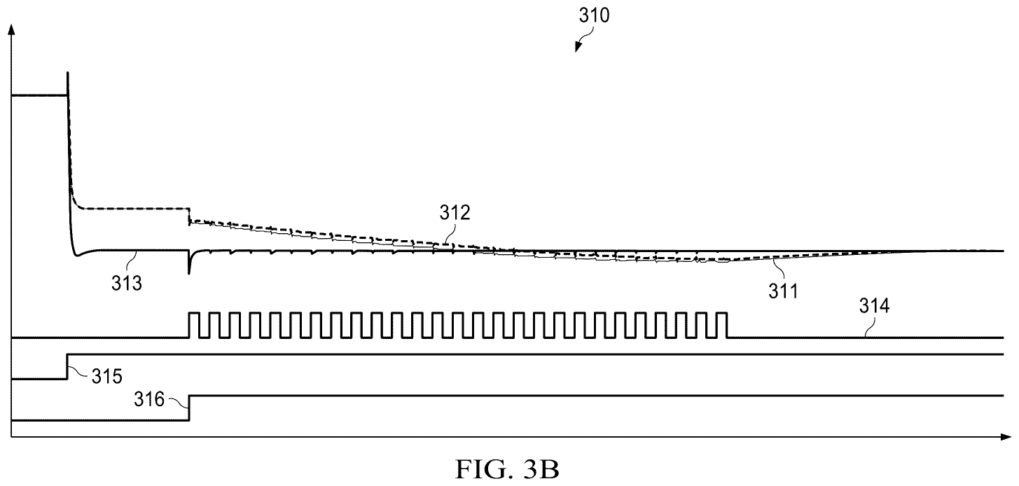

Referring also to FIGS. 3A and 3B, FIG. 3A shows a graph 300 of signals in the memory circuit of FIGS. 1-1D with the clamp transistors MC1-MCn configured to limit bit-cell drain-source voltage to mitigate bitline drift towards ground for multiple read operations and/or for lengthy standby mode operation while the device remains powered. The graph 300 includes a curve 301 that shows the bitline voltage of the first bitline 110 (BL1) as a function of time, as well as a second curve 302 that shows the bitline voltage of the final or “n^{th}” bitline 130 (BLn). The graph 300 also includes a curve 303 that shows the voltage BIASP of the bias node 108, a curve 304 that shows a clock signal (CLK), a curve 305 that shows a bias enable logic or control signal BIASEN, and a curve 306 that shows the read control signal READ in the semiconductor device 100 of FIGS. 1-1D above. In addition, the graph 300 of FIG. 3A includes a curve 308 that shows the voltage CLMP of the clamp node 106 during powered operation of the semiconductor device 100.

FIG. 3B shows a graph 310 of signals in the baseline memory circuit 160 and baseline layout 162 of FIGS. 1E, IF1 and 1F2 that shows bit-cell drain-source voltage drift towards ground for multiple read operations without bitline clamp transistors. The graph 310 includes a curve 311 that shows the bitline voltage of the first bitline bl1 (FIG. 1E) as a function of time, as well as a second curve 312 that shows the bitline voltage of the final bitline bl4, a curve 313 that shows the voltage of the bias node (biasp in FIG. 1F1), a curve 314 that shows a clock signal, a curve 315 that shows a bias enable logic or control signal and a curve 316 that shows a read control signal. As seen in FIG. 3B, the memory circuit 160 and baseline layout 162 of FIGS. 1E, IF1 and 1F2 has no way to counteract downward drift or leakage during repetitive read operations and the bitline voltages shown in the curves 311 and 312 drift downward with time. This can lead to undesired turn off of the bias transistors MP1-MPn if the associated bitline voltage is reduced to the point where the gate of the bias transistors MP1-MPn is not sufficiently low to turn the bias transistors MP1-MPn on or to keep it on during a read operation, for example, causing an erased bit-cell to be read as being in the programmed state.

In contrast, the bitline voltage curves 301 and 302 in the graph 300 of FIG. 3A are regulated by the connected clamp transistors MC1-MCn, which limit bit-cell drain-source voltage and prevent or inhibit significant drop in the voltages at the bitlines 110, 120, 130 in FIGS. 1-1D, even in the presence of multiple read operations and/or for lengthy standby mode operation while the device remains powered with bitline leakage to ground. The clamp transistors MC1-MCn actively monitor the bitline voltages during read operations (e.g., while READ is asserted), and even if the bit-cell is erased (or unprogrammed), the clamp transistors help ensure that the cell transistor drain-source voltage is less than or equal to VDD-2 V in one example, irrespective of bitline leakage or coupling. The bitlines are clamped with respect to the supply node 101 (e.g., VDD) during standby mode operation (e.g., when neither READ nor PROG are asserted in FIG. 1) and cannot drift significantly towards the reference node voltage GND based on leakage current. The clamp transistors MC1-MCn provide a no-cost compact solution that addresses the problems independent of manufacturing process variations or tolerances, supply voltage variations and/or temperature variations (PVT agnostic) to accommodate reliable memory circuit operation independent of leakage variations. Clamp solutions can be implemented with minimum sized PMOS transistors MC1-MCn in diode configuration or by other suitable connected clamp circuitry, where the described examples have little or no impact on read performance because little capacitance is added to the bitlines 110, 120, 130 by connection of the clamp transistors MC1-MCn. In addition, the described examples add no area overhead (e.g., see same H and W dimensions in FIGS. 1B1, 1B2, 1F1 and 1F2). Moreover, the described examples do not consume much or any additional power as there is no need for external or internal reference currents or additional current mirrors to implement the clamping solution provided by the clamp transistors MC1-MCn. The described solutions can be used in any type or form of electronic memory and can be applied to any memory system where accurate clamping is beneficial for bit-cell reliability.

The above examples are merely illustrative of several possible implementations of various aspects of the present disclosure, wherein equivalent alterations and/or modifications will occur to others skilled in the art upon reading and understanding this specification and the annexed drawings. Modifications are possible in the described examples, and other implementations are possible, within the scope of the claims.

What is claimed is:

1. A semiconductor device, comprising:
a cell transistor coupled to a bitline;
a bias transistor coupled to the bitline and to a bias node; and
a clamp transistor coupled between the bitline and a clamp node.

2. The semiconductor device of claim 1, wherein the clamp transistor is an n-channel transistor having a gate directly connected to the bitline, a source directly connected to the bitline, and a drain directly connected to the clamp node.

3. The semiconductor device of claim 1, wherein: the bias transistor has a first width; the clamp transistor has a second width; and the first width is greater than the second width.

4. The semiconductor device of claim 3, wherein the first width is greater than twice the second width.

5. The semiconductor device of claim 1, further comprising a further transistor coupled between the clamp node and a supply node.

6. The semiconductor device of claim 5, further comprising a logic circuit coupled to a control terminal of the further transistor.

7. The semiconductor device of claim 5, further comprising another transistor coupled between the clamp node and a reference node.

8. The semiconductor device of claim 7, further comprising a logic circuit coupled to a control terminal of the other transistor.

9. The semiconductor device of claim 1, further comprising a current source coupled between the bias transistor and a reference node.

10. A memory circuit, comprising:
an array of memory cell transistors coupled to respective bitlines;
bias transistors, each having a source, a drain, and a gate, the source of each bias transistor coupled to a respective one of the bitlines;
a bias node coupled to the gates of the bias transistors;
a current source having first and second terminals, the first terminal coupled to the bias node, and the second terminal coupled to a reference node; and
clamp transistors, each having a source, a drain, and a gate, the gate and source of each clamp transistor coupled to a respective one of the bitlines, and the drain of each clamp transistor coupled to a clamp node.

11. The memory circuit of claim 10, wherein: individual ones of the bias transistors have a first width; individual ones of the clamp transistors have a second width; and the first width is greater than the second width.

12. The memory circuit of claim 11, wherein the first width is greater than twice the second width.

13. The memory circuit of claim 10, further comprising a further transistor coupled between the clamp node and a supply node.

14. The memory circuit of claim 13, further comprising a logic circuit coupled to a control terminal of the further transistor.

15. The memory circuit of claim 10, comprising another transistor coupled between the clamp node and a reference node.

16. A method, comprising:
forming bias transistors on or in a semiconductor layer, the bias transistors in a first row and spaced apart from one another along a first direction and having respective gates with a first width along a second direction that is orthogonal to the first direction;
forming clamp transistors in a parallel second row on or in the semiconductor layer, the clamp transistors spaced apart from one another along the first direction and spaced apart from respective ones of the bias transistors along the second direction and having respective gates with a second width along the second direction that is less than the first width;
connecting a source of the bias transistors to a respective one of bitlines of a memory array;
connecting gates of the bias transistors to a bias node; and
connecting each of the clamp transistors between a clamp node and a respective one of the bitlines.

17. The method of claim 16, wherein the first width is greater than twice the second width.

18. The method of claim 16, further comprising connecting a source and gate of each of the clamp transistors to a respective one of the bitlines and connecting a drain of each of the clamp transistors to the clamp node.

19. The method of claim 16, further comprising forming the bitlines extending above the semiconductor layer along the first direction, the bitlines spaced apart from one another along the second direction and above the bias transistors and the clamp transistors.

20. The method of claim 19, further comprising forming the clamp node extending above the bitlines along the second direction.
